(19) United States
(12) Patent Application Publication
(10) Pub. No.: US 2012/0152299 A1
(43) Pub. Date: Jun. 21, 2012

(54) Solar Cell And Solar Cell Module With Improved Read-Side Electrodes, And Production Method

(75) Inventors: Oliver Schultz-Wittmann, Sunnyvale, CA (US); Stefan Glunz, Freiburg (DE); Martin Hermle, Freiburg (DE)

(73) Assignee: FRAUNHOFER-GESELLSCHAFT ZUR FÖRDERUNG DER ANGEWANDTEN FORSCHUNG E.V., Munchen (DE)

(21) Appl. No.: 12/513,217

(22) PCT Filed: Oct. 31, 2007
(86) PCT No.: PCT/EP2007/009461

§ 371 Date: Jan. 15, 2010

(30) Foreign Application Priority Data
Nov. 3, 2006 (DE) 10 2006 052 018.1

(51) Int. Cl. H01L 31/05; H01L 31/18; H01L 31/0224

(52) U.S. Cl. 136/244; 136/256; 438/98; 257/E31.124

(57) ABSTRACT

The present invention relates to rear-side contact solar cells and also solar cell modules manufactured therefrom, said modules having a special electrode structure, and also to a method for the production thereof. The electrodes, via which the current of the rear-side contact cell is tapped, are thereby separated by an insulating layer from the finger contacts which are in contact with the n- or p-semiconductor element of the solar cell through an insulating layer. The method makes possible a substantial simplification relative to the production methods described in the state of the art by means of spatial decoupling of the structuring of the electrodes from the solar cell.

### BACKGROUND OF THE INVENTION

The present invention relates to rear-side contact solar cells and also solar cell modules manufactured therefrom, said modules having a special electrode structure. The electrodes, via which the current of the rear-side contact cell is tapped, are thereby separated by an insulating layer from the finger contacts which are in contact with the n- or p-semiconductor element of the solar cell through an insulating layer. A method for the production of a rear-side solar cell of this type is likewise described.

Solar cells which correspond to the state of the art have two current collection bars (busbars) which are placed respectively on one side of the solar cell and serve for external contacting.

FIG. 1 shows a schematic representation of such a rear-side-contacted silicon solar cell 1. Both electrodes are situated on the rear-side of the cell. The current collection bars (busbars 2, 2′) are situated at the cell edge whilst the finger contacts 3, 3′ respectively extend into the surface of the solar cell.

In the present state of the art two problems are hereby posed:

1. Busbars are required which enable contacting of the solar cell. These “busbars” occupy a relatively large space in order to be able to be contacted well technologically. The geometric size leads to considerable losses in the solar cell. On the side which taps the minority charge carriers, the collection properties and hence the short circuit current are significantly reduced. On the side which contacts the majority charge carriers, high series resistance losses which lead to a reduction in the filling factor are significant.
2. The fingers which contact the semiconductor and extend over the entire length of the solar cell must have very high conductivity in order to minimise series resistance losses. Since the fingers cannot be too wide (narrower than 1 mm), they must be very high (higher than 10 μm) in order to have an adequate conduction cross-section.

Furthermore, rear-side contact solar cells are known from the state of the art (for example U.S. Pat. No. 4,927,770 and U.S. Pat. No. 6,426,568) in which p- and n-doped regions are connected to current-collecting regions by means of contacts which pass through the insulating layer. However, these contact layers are disposed one above the other, therefore there is a requirement here to apply at least one further insulating layer between these contact regions. The production of complex structures of this type is very complex and cost-intensive since such structures must always be produced in several steps which include in part a plurality of high-temperature steps.

### SUMMARY OF THE INVENTION

It is hence the object of the present invention to provide a rear-side contact solar cell with a simple construction in which the electrical losses in the solar cell are minimised. Furthermore, it is the object of the invention to configure a rear-side contact solar cell in such a manner that as great as possible variability is maintained with respect to the geometric configuration of the finger contacts.

This object is achieved with the rear-side contact cell having the features of patent claim 1 and also the solar cell module having the features of claim 18. A method for the production of such a rear-side solar cell is indicated in claim 22. The respectively dependent claims thereby represent advantageous developments.

According to the invention, a rear-side contact cell with a surface of at least 100 cm² is provided, having at least one p-finger contact which is disposed on the rear-side and is in electrical contact with the p-semiconductor of the solar cell and also at least one n-finger contact which is in electrical contact with the n-semiconductor of the solar cell, at least two means (contacts) for tapping the current being present, which means are applied on at least one layer made of insulating material which spatially separates the finger contacts from the means, and the means being contacted through the at least one layer, the at least one means 5 being contacted electrically with the at least one p-finger contact and the at least one means 5′ with the at least one n-finger contact. In contrast to the state of the art, the means (contacts) for tapping the current are not disposed one above the other but adjacently, which substantially simplifies the construction and the method for the production of a solar cell according to the invention.

Many advantages with respect to the configuration of the solar cells are produced by such a solar cell.

1. The finger contacts can thereby have a thinner and narrower configuration, as a result of which the production costs are lowered since high-quality, conductive material can be dispensed with. It emerges thereby as an additional positive effect that the construction of lighter solar cells is made possible.
2. The structuring or the application of the contacts for tapping the current can be produced by a large number of suitable methods, for example by lift-off methods or by rear-etching after masking in only one method step.
3. Application of busbars on the cell is likewise unnecessary. This leads likewise to an increase in efficiency of the solar cell and to a saving in production costs due to substantially simplified production courses. A further synergetic side-effect is a weight reduction in the solar cell.
4. A connection according to the invention of the electrical contacts of the solar cell enables a simplified module connection if a plurality of solar cells are combined to form one module.
5. The invention enables an extensive decoupling of the production of the conductive strips and the structuring of the same on the insulating substrate. By using the holes in the substrate, the selection of material in particular for the insulating layer is not restricted.
6. Since the solar cells are less stressed mechanically due to the simplified production method which is accomplished with fewer method steps, the breakage rate is lowered in addition. Alternative, simpler methods than described e.g. in U.S. Pat. No. 4,927,770 and U.S. Pat. No. 6,426,568 can be applied. As a result, lowering of production costs is achieved. In addition, the requirement that the production process requires to be adapted to solar cell-specific requirements (such as e.g. temperature, mechanical force) can be dispensed with. In addition, fewer rejects are produced and the lifespan of the solar cells can be increased.
7. Since the means for tapping the current are disposed adjacently on the at least one insulating layer, there are no further requirements such as, e.g. as in the case of applying the contacts one above the other, the necessity for a further insulating layer for insulating these contacts from each other.
8. As a result of the configuration according to the invention, an extremely efficient and economical production of large-area solar cells is possible. A method, as indicated for example in U.S. Pat. No. 6,423,568, would be completely unsuitable solely for economical reasons for the production of large solar cells. Lithographic processes and/or metallisation processes can no longer be controlled cleanly in the case of such large-area substrates—such as for example silicon wafers—and lead only to unsatisfactory results.

It is thereby advantageous if the means have at least one strip conductor and also at least one busbar which are in electrical contact with each other. With respect to the orientation relative to the finger contacts which are applied directly on the solar cell and are generally configured parallel to each other, the orientation of the at least one strip conductor of the means for tapping the current can be disposed in any manner. It is thereby essential that the at least one strip conductor is disposed relative to the solar cell such that contacting of all finger contacts on the solar cell of the same polarity is made possible. For example, an arrangement of the at least one strip conductor which extends perpendicular, i.e. rotated by 90°, relative to the finger contacts is hence conceivable. The geometric arrangement of the busbar is likewise arbitrary; in an advantageous embodiment the busbar extends however parallel to the finger contacts applied on the solar cell. Furthermore, it is advantageous if more than one strip conductor is present for contacting the finger contacts. This enables a maximum current output and minimisation of current losses due to the electrical resistance of the finger contacts.

The at least two means are thereby made of electrically conductive material, the conductive material is thereby configured advantageously from the group comprising copper, nickel, tin, silver, gold, aluminium, tungsten, titanium, palladium and also alloys hereof and/or layer sequences thereof.

It is a further advantage of the invention that the layer thickness of the respective means can be configured respectively according to the purpose of use of the solar cell and can vary over a wide range. In an advantageous embodiment, the layer thickness is however between 1 nm and 100 nm, preferably between 5 nm and 80 nm, particularly preferred between 10 nm and 50 nm.

Due to the configuration of the solar cell according to the invention, the finger contacts for contacting the semiconductor layers can have a very thin configuration. Advantageously, the layer thicknesses here are in a range between 0.01 nm and 10 nm, preferably between 0.02 nm and 5 nm, particularly preferred between 0.03 nm and 3 μm.

The insulating layer is in addition configured advantageously as a continuous rear-side of the solar cell. The insulating layer is thereby perforated at the points at which the production of the electrical contact between the at least two means for tapping the current and the at least two finger contacts is effected.

The insulating layer is not thereby restricted to special materials, it is merely essential that the material is an electrical insulator. Advantageously, materials are thereby used, selected from the group consisting of glass, silicon, silicon oxide, aluminium oxide, organic paints, Pertinax, EVA films, plastic material films and also mixtures and/or layer sequences thereof.

The insulating layer is not subject to any specific restriction with respect to the thickness thereof. The layer thickness of the insulating material is however preferably between 1 nm and 2,000 nm, preferably between 2 nm and 1,000 nm, particularly preferred between 5 nm and 500 nm.

For example, the insulating substrate can be chosen to be very thick in order to ensure high durability of the insulation. The choice of the material components is extensively decoupled from the solar cell production.

In a further advantageous embodiment, the at least one strip conductor of the means has at least one hole via which contacting with the respective finger contacts is effected. With respect to the dimensions of the at least one hole, it is advantageous if the at least one hole has a diameter of 0.1 mm to 2 mm, preferably of 0.2 mm to 1 mm, particularly preferred of 0.25 mm to 0.6 mm. The holes are not thereby restricted to any special geometric shape. For example, these can be configured as circles, squares or n-polygons which can also be irregular.

It is likewise advantageous if the contacting of the means with the respective finger contacts is configured as a soldered contact.

It has proved to be a particular advantage of the invention that, in the case of the solar cell, the use of busbars which are disposed on the solar cell rear-side can be dispensed with, as a consequence of which the advantages already mentioned further back result.

Furthermore, it is advantageous if the surface of the solar cell is at least 120 cm², preferably at least 140 cm².

The finger contacts of the solar cell can likewise have an exceptionally thin configuration. For example, it is favourable if the finger contacts have a height of between 0.1 and 10 nm, preferably between 0.2 and 5 nm, particularly preferred between 0.5 and 3 nm and/or a width between 100 and 1,000 nm, preferably between 150 and 750 nm, particularly preferred between 200 and 500 nm.

Of course at least two solar cells can be connected in parallel or in series in order to increase the current output.

Hence a solar cell module which contains at least two above-described solar cells is also provided according to the invention.

In an advantageous embodiment, the solar cells are applied thereby such that the at least one insulating layer is configured continuously over all the solar cells as a rear-side layer. In this case, the insulating substrate can comprise a surface (rear-side) of a plurality of solar cells. The substrate can be chosen with respect to stability such that it endows the solar cell module with a large part of the required stability.

As a further advantage, the particular simple electrical connection of the solar cells to each other is possible, in which the solar cells are connected in an integrated manner.

According to the invention, a method for the production of an above-indicated rear-side solar cell is likewise indicated, said solar cell being characterised by the following steps:

a) application at least of two means (5, 5′) adjacently on one side of an insulating material which is constructed from at least one layer (4) so that the two means are connected to the at least one layer (4) in a form fit,
b) application of the composite of step a) with the orientated-away side which has the means on a solar cell which has at least one p-finger contact (3) and at least one n-finger contact (3′),
c) electrical contacting in regions of the means (5, 5′) with the finger contacts (3, 3′) through the at least one insulating layer (4) so that respectively one p-finger contact (3) or one n-finger contact (3′) is contacted electrically with one means (5 or 5′).

It is thereby an essential feature according to the invention that the production of the contact structure of the means for contacting the finger contacts of the solar cell is separated spatially from the solar cell. Since solar cells (in particular solar cells based on monocrystalline wafers) are manufactured usually from highly pure silicon in order to increase the efficiency, it is absolutely necessary that all the operating steps which are effected directly at or on the surface of the solar cell are effected under highly pure conditions. This is associated with significant complexity (e.g. clean rooms etc.) which involves high costs. According to the invention, the conductor structure via which the tapping of the current is effected can now be effected in one operating step in which these complex measures can be dispensed with. The production of the conductor layer on the insulating substrate is accordingly effected under standard conditions (i.e. no special measures for maintaining purity need be adopted), merely in the steps in which the thus pre-produced composite is applied on the solar cell and is contacted electrically with the finger contacts need the operation take place sufficiently cleanly. Relative to the state of the art, a substantial simplification of the method is hence achievable.

In the case of the method according to the invention it is thereby irrelevant how the at least two means (5, 5′) are applied adjacently on one side of an insulating material since the fixing is effected only in the subsequent step. Consequently, fixing of the means on the insulating substrate is also of course effected. It is however advantageous if the means are soldered, welded and/or glued on in step a).

In a further advantageous embodiment, the obtained composite is fixed on the solar cell in step b), the fixing being effected advantageously by gluing and/or soldering. However mechanical fixing (e.g. by pressing on or clamping) is likewise possible.

Finally the electrical contacting is effected advantageously by soldering. One means respectively is thereby connected through the insulating layer to respectively one of the at least one finger contacts. There should thereby be understood according to the invention that a means is contacted electrically with the entirety of the p-finger contacts of the solar cell, whilst the other means is brought in electrical contact with the entirety of the n-finger contacts.

### BRIEF DESCRIPTION OF THE FIGURES

The invention is described subsequently in more detail with reference to the accompanying Figures without however wishing to restrict the invention however to the special features indicated there.

There are thereby shown

FIG. 1 a rear-side contact solar cell, as is known from the state of the art; the light 9 thereby impinges on the solar cell from the underside.

FIG. 2 an arrangement according to the invention of the contacting device, electrodes and the insulating substrate being represented here.

FIG. 3 a rear-side contact solar cell according to the invention, having finger contacts, an insulating layer and also electrodes applied for tapping the current.

### DETAILED DESCRIPTION OF THE PREFERRED EMBODIMENTS

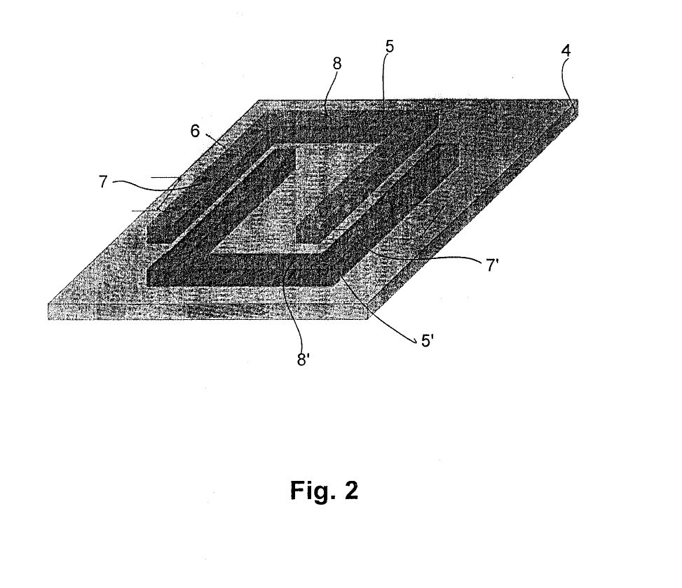

A contacting device is illustrated in FIG. 2. The latter consists of the electrically insulating substrate 4 and the means 5 and 5′ applied thereon. The contacting device is produced separately from the solar cell 1.

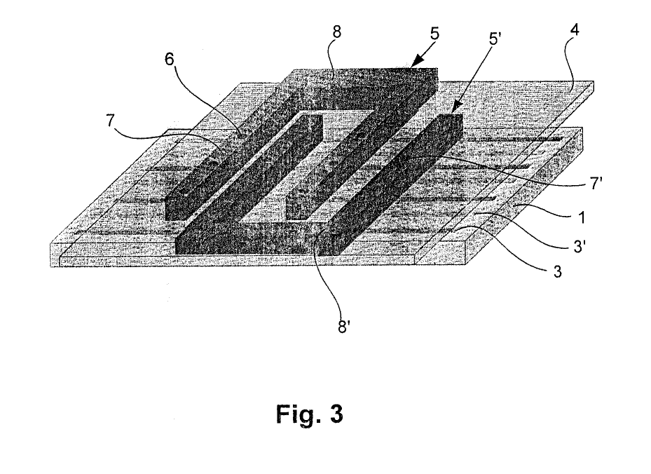

In FIG. 3, a solar cell 1 according to the invention is also represented. The solar cell 1 thereby has only finger contacts. These are applied directly on the solar cell and separated spatially by an insulating plane 4, which is produced from an insulating material, from the electrodes 5, 5′ with which they are connected via contacts which pass through the insulating layer. Busbars on the solar cell are hence superfluous.

The electrically insulating substrate prevents the short circuit between the n- and the p-electrode when the contacting unit is placed on the rear-side of the solar cell 1 (see FIG. 3) and the strip conductors 7, 7′ of the two means 5, 5′ hence extend transversely relative to the finger contacts 3, 3′.

The actual solar cell 1 thereby only has contact fingers 3, 3′. The busbars 8, 8′ are situated on a second plane on the electrically insulating substrate 4 and are contacted through holes 6 to the respective contact fingers 3, 3′, e.g. by soldered contacts which extend through the insulating layer 4. The geometric extensions of the holes 6 can be configured independently of the solar cell geometry.

An electrically conductive connection between the solar cell 1 and the strip conductors 7, 7′ can be produced on the second plane through the holes 6. When using two strip conductors 7 on the upper plane (as shown in FIGS. 2 and 3), the charge carriers still require only approx. a quarter of the conductivity of the fingers 3, 3′ to be made available. The required conductivity LF of the fingers 3, 3′ can be estimated in general as:

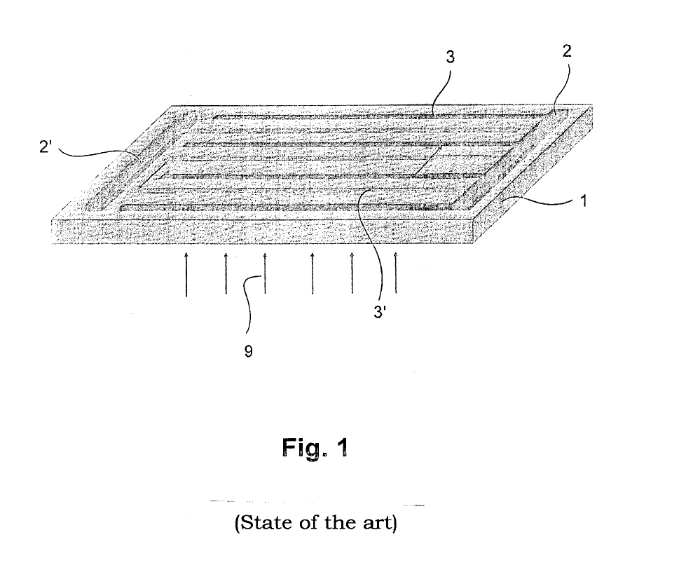

LF_{standard}*1/1(1+n)=LF_{new} with n=number of strip conductors 7 on the insulating substrate 4. In addition, the busbars 2, 2′ (see FIG. 1) on the solar cell 1 can be omitted and only a stripe pattern of p- and n-fingers 3, 3′ is still necessary. This simplifies considerably the production processes of the rear-side contact cells 1.

If the second plane has a large-area configuration, a simplified module connection of a large number of solar cells 1 can be undertaken. Via the strip conductors 7, 7′ which are applied on the second plane, the solar cells are connected in an integrated manner on the electrically insulating substrate 4. In this case, the electrically insulating substrate 4 forms the rear-side of the module. It is thereby advantageous if the rear-side of the module is protected by further precautions (e.g. a protective layer made of an inert material such as for example plastic materials) from weathering, environmental influences and/or moisture.

What is claimed is:

1. Rear-side contact solar cell (1) with a surface of at least 100 cm², having at least one p-finger contact (3) which is disposed on the rear-side and is in electrical contact with a p-semiconductor of the solar cell (1) and also at least one n-finger contact (3′) which is in electrical contact with a n-semiconductor of the solar cell (1), at least two means (5, 5′) for tapping the current being present, which means are applied adjacently on at least one layer (4) made of insulating material which spatially separates the finger contacts (3, 3′) from the means (5, 5′), and the means (5, 5′) being contacted through the at least one layer (4), the at least one means (5) being contacted electrically with the at least one p-finger contact (3) and the at least one means (5′) with the at least one n-finger contact (3′).

2. Solar cell (1) according to claim 1, wherein the means (5, 5′) have at least one strip conductor (7) and also at least one busbar (8) which are in electrical contact with each other.

3. Solar cell (1) according to claim 1, wherein the means (5, 5′) are made of electrically conductive material.

4. Solar cell (1) according to claim 3, wherein the conductive material is selected from the group consisting of copper, nickel, tin, silver, gold, aluminium, tungsten, titanium, palladium and also alloys hereof and/or layer sequences thereof.

5. Solar cell (1) according to claim 1, wherein the layer thickness of the means (5, 5′) is between 1 μm and 100 μm, preferably between 5 μm and 80 μm, particularly preferred between 10 μm and 50 μm.

6. Solar cell (1) according to the preceding claim, wherein the at least one insulating layer (4) forms the rear-side of the solar cell (1).

7. Solar cell (1) according to claim 1, wherein the at least one insulating layer (4) is perforated at the points at which the production of the electrical contact between the at least two means (5, 5′) for tapping the current and the at least two finger contacts (3, 3′) is effected.

8. Solar cell (1) according to claim 1, wherein the at least one insulating layer (4) contains materials selected from the group consisting of glass, silicon, silicon oxide, aluminium oxide, organic paints, Pertinax, EVA films, plastic material films and also mixtures and/or layer sequences hereof.

9. Solar cell (1) according to claim 1, wherein the at least one layer (4) made of insulating material has a thickness between 1 μm and 2,000 μm, preferably between 2 μm and 1,000 μm, particularly preferred between 5 μm and 500 μm.

10. Solar cell (1) according to claim 2, wherein the at least one strip conductor (7) of the means (5, 5′) has at least one hole (6) via which contacting with the respective finger contacts (3, 3′) is effected.

11. Solar cell (1) according to the preceding claim, wherein the at least one hole (6) has a diameter of 0.1 mm to 2 mm, preferably of 0.2 mm to 1 mm, particularly preferred of 0.25 to 0.6 mm.

12. Solar cell (1) according to claim 1, wherein the contacting of the means (5, 5′) with the respective finger contacts (3, 3′) is configured as a soldered contact.

13. Solar cell (1) according to claim 1, wherein the solar cell (1) has no busbars (2).

14. Solar cell (1) according to claim 1, wherein it is connected electrically to at least one further solar cell (1).

15. Solar cell (1) according to claim 1, wherein the surface is at least 120 cm², preferably at least 140 cm².

16. Solar cell (1) according to claim 1, wherein the finger contacts (3, 3′) have a height of between 0.1 and 10 μm, preferably between 0.2 and 5 μm, particularly preferred between 0.5 and 3 μm.

17. Solar cell (1) according to claim 1, wherein the finger contacts (3, 3′) have a width between 100 and 1,000 μm, preferably between 150 and 750 μm, particularly preferred between 200 and 500 μm.

18. Solar cell module, comprising at least two solar cells (1) according to solar cell (1) of claim 1.

19. Solar cell module according to the preceding claim, wherein the solar cells (1) are connected in parallel or in series.

20. Solar cell module according to claim 18, wherein the at least one isolating layer (4) is configured continuously over all the solar cells as a rear-side layer.

21. Solar cell module according to claim 18, wherein the solar cells (1) are connected in an integrated manner via the at least two means (5, 5′).

22. Method for the production of a rear-side contact solar cell (1), characterised by the following steps:
a) application at least of two means (5, 5′) adjacently on one side of an insulating material which is constructed from at least one layer (4) so that the two means are connected to the at least one layer (4) in a form fit,
b) application of the composite from step a) with an orientated-away side which has the means on a solar cell which has at least one p-finger contact (3) and at least one n-finger contact (3′),
c) electrical contacting in regions of the means (5, 5′) with the finger contacts (3, 3′) through the at least one insulating layer (4) so that respectively one p-finger contact (3) or one n-finger contact (3′) is contacted electrically with one means (5 or 5′).

23. Method according to claim 22, wherein the means (5, 5′) are soldered, welded and/or glued on in step a).

24. Method according to claim 23, wherein the composite obtained from step a) is fixed on the solar cell in step b).

25. Method according to the preceding claim, wherein the fixing is effected by gluing and/or soldering.

26. Method according to one of the claim 22, wherein the electrical contacting of respectively one means (5 or 5′) with respectively one of the at least one finger contacts (3 or 3′) is effected by soldering in step c).
